(19) United States
(12) Patent Application Publication
(10) Pub. No.: US 2025/0029864 A1
(43) Pub. Date: Jan. 23, 2025

(54) CHUCK TABLE AND SEMICONDUCTOR PACKAGE MANUFACTURING METHOD USING THE SAME

(71) Applicant: SAMSUNG ELECTRONICS CO., LTD., SUWON-SI (KR)

(72) Inventors: KANG GYUNE LEE, Suwon-si (KR); SANG-WON LEE, Suwon-si (KR); HYEON HWANG, Suwon-si (KR); Younhwan SHIN, Suwon-si (KR)

(21) Appl. No.: 18/439,884

(22) Filed: Feb. 13, 2024

(30) Foreign Application Priority Data
Jul. 18, 2023 (KR) 10-2023-0092988

(51) Int. Cl. H01L 21/683; H01L 21/67; H01L 21/687

(52) U.S. Cl. CPC H01L 21/6838; H01L 21/67092; H01L 21/68785

(57) ABSTRACT

A chuck table includes a support part receiving a package substrate. The package substrate includes a package area having semiconductor packages arranged thereon and a scrap area surrounding the package area. A package pad part is between the support part and the package substrate and directly contacts the package area. A scrap pad part is disposed between the support part and the package substrate and directly contacts the scrap area. A vacuum pipe extends through the package pad part and extends into the support part. The vacuum pipe has vacuum pressure applied thereto and has the vacuum pressure released therefrom. A fixing device is connected to the vacuum pipe. The fixing device moves closer to an upper surface of the scrap area as the vacuum pressure is applied to the vacuum pipe, and moves away from the upper surface of the scrap area as the vacuum pressure is released.

### CROSS-REFERENCE TO RELATED APPLICATION

This application claims priority under 35 U.S.C. § 119 to Korean Patent Application No. 10-2023-0092988, filed on Jul. 18, 2023 in the Korean Intellectual Property Office, the disclosure of which is incorporated by reference in its entirety herein.

### 1. TECHNICAL FIELD

The present disclosure relates to a chuck table and a semiconductor package manufacturing method using the same.

### 2. DISCUSSION OF RELATED ART

During the manufacture of a plurality of semiconductor packages, the plurality of semiconductor packages may be arranged on a package substrate and integrally manufactured. The plurality of semiconductor package may then be separated into individual semiconductor packages through a process of cutting using a sawing device, such as in a singulation process. The package substrate may include a package area included in a semiconductor package after being cut through a singulation process and a scrap area that includes scrap after being cut through the singulation process.

A cutting device for manufacturing a semiconductor package may include a chuck table that cuts a package substrate into package units using a blade and fixes the package substrate in a vacuum suction method during the cutting process.

### SUMMARY

Embodiments of the present disclosure reduce damage to solder balls of a semiconductor package due to scrap during a cutting process.

According to an embodiment of the present disclosure, a chuck table includes a support part receiving a package substrate. The package substrate includes a package area having a plurality of semiconductor packages arranged thereon and a scrap area surrounding the package area. The scrap area does not include the plurality of semiconductor packages. A package pad part is disposed between the support part and the package substrate. The package pad part directly contacts the package area. A scrap pad part is disposed between the support part and the package substrate. The scrap pad part directly contacts the scrap area. A vacuum pipe extends through the package pad part and extends into the support part. The vacuum pipe has vacuum pressure applied thereto and has the vacuum pressure released therefrom. A fixing device is connected to the vacuum pipe. The fixing device moves closer to an upper surface of the scrap area as the vacuum pressure is applied to the vacuum pipe, and moves away from the upper surface of the scrap area as the vacuum pressure is released from the vacuum pipe.

According to an embodiment of the present disclosure, a chuck table includes a support part receiving a package substrate. The package substrate includes a package area having a plurality of semiconductor packages arranged thereon and a scrap area surrounding the package area. A package pad part is disposed between the support part and the package substrate. The package pad part directly contacts the package area. A scrap pad part is disposed between the support part and the package substrate. The scrap pad part directly contacts the scrap area. A vacuum pipe extends through the package pad part and extends into the support part. The vacuum pipe has vacuum pressure applied thereto and has the vacuum pressure released therefrom. A fixing device is connected to the vacuum pipe and is driven by the vacuum pressure applied to the vacuum pipe. The fixing device includes a compression member compressed by the vacuum pressure applied to the vacuum pipe and having a restoring force. A moving member connected to the compression member. The moving member is movable in the vacuum pipe by the application or release of the vacuum pressure. A fixing member is connected to the moving member and has a distance from the scrap area adjusted according to a moving direction of the moving member.

According to an embodiment of the present disclosure, a semiconductor package manufacturing method includes preparing a package substrate including a package area having a plurality of semiconductor packages arranged thereon and a scrap area surrounding the package area. The package substrate is positioned on a chuck table including a vacuum pipe that adsorbs the package area and a fixing device that is connected to the vacuum pipe and positions and fixes the scrap area. Vacuum pressure is applied to the vacuum pipe. The package substrate is sawed to singulate the plurality of semiconductor packages. The vacuum pressure to the vacuum pipe is released. In the applying of the vacuum pressure to the vacuum pipe, the fixing device approaches an upper surface of the scrap area. In the releasing of the vacuum pressure to the vacuum pipe, the fixing device moves away from the upper surface of the scrap region.

According to an embodiment of the present disclosure, it is possible to reduce damage to solder balls of a semiconductor package due to scrap during a cutting process.

### BRIEF DESCRIPTION OF THE DRAWINGS

FIG. 1 illustrates a cross-section view of a chuck table according to an embodiment of the present disclosure.

FIG. 2 illustrates a top plan view of the chuck table of FIG. 1 viewed from above according to an embodiment of the present disclosure.

FIG. 3 illustrates a cross-sectional view of the chuck table of FIG. 1 according to an embodiment of the present disclosure.

FIG. 4 illustrates a top plan view of the chuck table of FIG. 1 viewed from above according to an embodiment of the present disclosure.

FIG. 5A and FIG. 5B illustrate enlarged views of area A of FIG. 1 according to embodiments of the present disclosure.

FIG. 6 illustrates an enlarged view of area B of FIG. 5A according to an embodiment of the present disclosure.

FIG. 7A and FIG. 7B respectively illustrate a fixing device according to embodiments of the present disclosure.

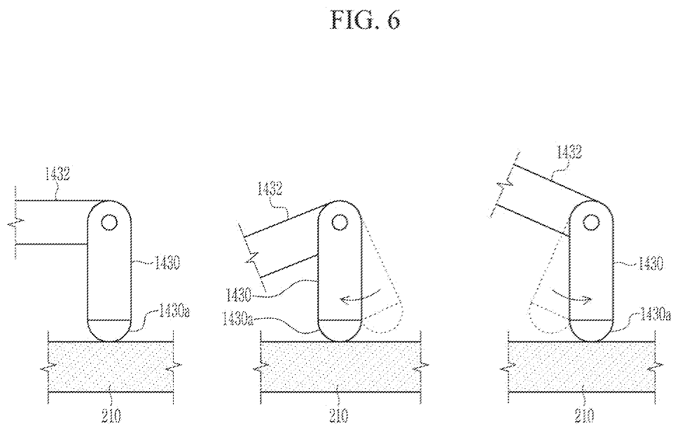

FIG. 6A and FIG. 8B respectively illustrate a fixing device according to embodiments of the present disclosure.

FIG. 9A and FIG. 9B respectively illustrate a fixing device according to embodiments of the present disclosure.

FIG. 10 to FIG. 13 are drawings of a semiconductor package manufacturing method using a chuck table according to an embodiment of the present disclosure.

### DETAILED DESCRIPTION OF EMBODIMENTS

The present disclosure will be described more fully hereinafter with reference to the accompanying drawings, in which non-limiting embodiments of the disclosure are shown. As those skilled in the art would realize, the described embodiments may be modified in various different ways, all without departing from the spirit or scope of the present disclosure.

To clearly describe the present disclosure, parts or portions that are irrelevant to the description may be omitted, and identical or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, no intervening elements may be present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a chuck table and a semiconductor package manufacturing method using the chuck table according to an embodiment will be described with reference to the accompanying drawings.

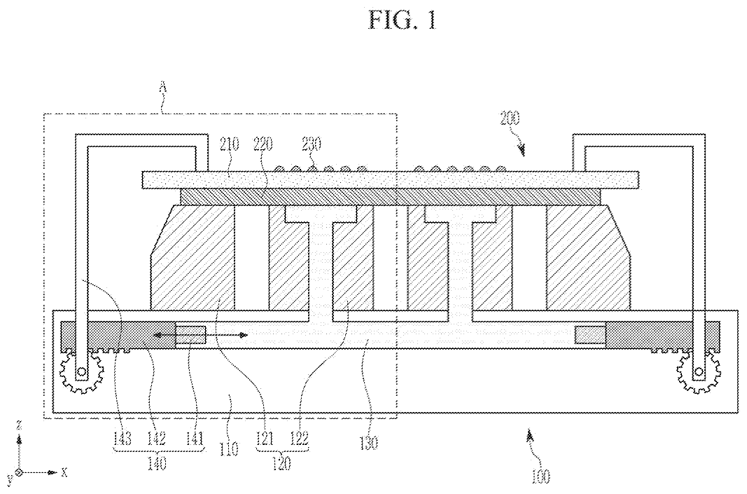

FIG. 1 illustrates a cross-section view of a chuck table 100 according to an embodiment. Referring to FIG. 1, the chuck table 100 according to an embodiment includes a support part 110, a pad part 120, a vacuum pipe 130, and a fixing device 140.

In an embodiment, the support part 110 may have a vacuum pipe 130 connected to a vacuum source that generates vacuum pressure therein. A package substrate 200 may be disposed on the support part 110. The pad part 120 may be disposed on the support part 110. In an embodiment, the support part 110 may include, for example, metal. However, embodiments of the present disclosure are not necessarily limited thereto.

The package substrate 200 may be disposed on the pad part 120. The package substrate 200 may include a plurality of semiconductor packages disposed thereon before a package sawing (e.g., a singulation) process is performed. In an embodiment, the package substrate 200 may include a substrate 210, a molding member 220, and a solder ball 230. In an embodiment, a semiconductor chip may be mounted on the substrate 210. The molding member 220 may cover the semiconductor chip mounted on the substrate 210. The solder ball 230 may be attached to a surface facing one surface of the substrate 210 covered by the molding member 220. For example, in an embodiment the solder ball 230 may be disposed on an opposite surface (e.g., in the z direction) of the substrate 210 than the surface of the substrate 210 that has the molding member 220 disposed directly thereon. The package substrate 200 may be disposed on the pad part 120 in an orientation so that the molding member 220 faces down.

In an embodiment, the package substrate 200 may include a package area in which a plurality of semiconductor packages are arranged and a scrap area surrounding the package area. For example, in an embodiment the package substrate 200 may include a plurality of semiconductor packages arranged in the form of a lattice that is repeatedly arranged in an x direction and a y direction. The package area may refer to an area that becomes a semiconductor package after being cut through a singulation process. The scrap area may refer to an area that becomes scrap after the singulation process. For example, the scrap may be a scrap portion of the package substrate 200 on which a semiconductor chip is not mounted on the substrate 210. The scrap may include only the substrate 210 and the molding member 220 without semiconductor chips.

In an embodiment, the solder ball 230 may be disposed on the substrate 210 corresponding to the package area. For example, a plurality of solder balls 230 may be arranged in a lattice shape in one package area. The solder ball 230 may not be formed on the substrate 210 corresponding to the scrap area.

The pad part 120 may be disposed between the support part 110 and the package substrate 200 (e.g., in the z direction). In an embodiment, the pad part 120 may include rubber. However, embodiments of the present disclosure are not necessarily limited thereto, and the pad part 120 may be made of other materials that are non-slip.

In an embodiment, the pad part 120 may include a package pad part 122 in direct contact with the package area of the package substrate 200 and a scrap pad part 121 in direct contact with the scrap area of the package substrate 200. The package pad part 122 may be disposed in a central area of the support part 110 in a plan view. In an embodiment, the scrap pad part 121 may be disposed on an edge area of the support part 110 so as to surround the package pad part 122 in a plan view (e.g., in the x and y directions). In a cross-sectional view, the scrap pad part 121 may be disposed on both sides with the package pad part 122 interposed therebetween.

In an embodiment, the package pad part 122 may include a plurality of package pads. The scrap pad part 121 may include a plurality of scrap pads. In an embodiment, the plurality of package pads may have a matrix array that is repeatedly arranged in the x direction and the y direction. The plurality of scrap pads may be disposed to surround the plurality of package pads. The plurality of scrap pads may be arranged in a line shape extending in the x direction and the y direction at one side of the outermost package pads among the plurality of package pads.

The plurality of package pads may be spaced apart from each other. The plurality of scrap pads may be spaced apart from each other. The package pad and the scrap pad adjacent to each other may be spaced apart from each other. For example, in an embodiment the plurality of package pads, the plurality of scrap pads, and the package pad and the scrap pads adjacent to each other may be respectively spaced apart from each other by a distance at which a blade cutting the package substrate 200 may be inserted without contacting package pads or scrap pads. For example, widths between the plurality of package pads, between the plurality of scrap pads, and between the package pad and the scrap pad adjacent to each other may be greater than a thickness of the blade.

In an embodiment, the vacuum pipe 130 may pass through the package pad part 122. For example, the vacuum pipe 130 may pass through upper and lower surfaces of the package pad part 122 vertically (e.g., in a z-direction) to extend into the support part 110. The vacuum pipe 130 may directly contact the package substrate 200 through the upper surface of the package pad part 122. Since the package substrate 200 is disposed above the pad part 120 in an orientation so that the molding member 220 faces down, the vacuum pipe 130 may directly contact the molding member 220 disposed directly above the upper surface of the package pad part 122. For example, in an embodiment a diameter of the vacuum pipe 130 adjacent to the upper surface of the package pad part 122 may be larger than a diameter of the vacuum pipe 130 passing through a middle portion of the package pad part 122 in the vertical direction and a lower surface of the package pad part 122. For example, the vacuum pipe 130 may have a T-shape. In this embodiment, since the vacuum pipe 130 has a wider contact area with the package substrate 200, adsorption force may be increased when vacuum pressure is applied.

In an embodiment, the vacuum pipe 130 passing through the package pad part 122 may extend into the support part 110 to be connected to each other. The vacuum pipe 130 may extend from a portion extending into the support part 110 to an edge portion of the support part 110. Here, the edge portion of the support part 110 may mean a side surface of the support part 110. The vacuum pipe 130 may extend from a portion extending into the support part 110 to pass under the scrap pad part 121.

For example, in an embodiment the vacuum pipe 130 may include a tubular member formed along the pipeline. As another example, the vacuum pipe 130 may be defined by a through hole formed in the package pad part 122 and an inner sidewall of the through hole formed in the support part 110 without a separate tubular member.

At least a portion of the vacuum pipe 130 may be connected to a vacuum source that generates vacuum pressure. When vacuum pressure is applied to the vacuum pipe 130, the package area of the package substrate 200 in direct contact with the package pad part 122 may be vacuum-adsorbed.

In an embodiment, the fixing device 140 may be coupled to the vacuum pipe 130. The fixing device 140 may be connected to a portion of the vacuum pipe 130 extending to the edge portion of the support part 110. In an embodiment, the fixing device 140 may be driven by vacuum pressure applied to the vacuum pipe 130. The fixing device 140 may position and fix the scrap area of the package substrate 200.

In the embodiment, the fixing device 140 may be connected to the vacuum pipe 130 to position and fix the scrap area of the package substrate 200. For example, in an embodiment the fixing device 140 may come closer to the upper surface of the scrap area as vacuum pressure is applied to the vacuum pipe 130. The fixing device 140 may move away from the upper surface of the scrap area as the vacuum pressure is released to be applied to the vacuum pipe 130.

In the embodiment, the fixing device 140 may include a compression member 141, a moving member 142, and a fixing member 143. In an embodiment, the compression member 141 may be compressed by vacuum pressure applied to the vacuum pipe 130. The compression member 141 may be disposed inside the vacuum pipe 130, and air may communicate with the inside of the vacuum pipe 130. In an embodiment, the compression member 141 may have a restoring force. A length of the compression member 141 may be reduced as it is compressed by the vacuum pressure, and may be restored to its original length as the vacuum pressure is removed. In an embodiment, the compression member 141 may include, for example, a spring or a pneumatic cylinder. However, embodiments of the present disclosure are not necessarily limited thereto.

In an embodiment, the moving member 142 may be connected to the compression member 141. In an embodiment, the moving member 142 may enter or exit the vacuum pipe 130 by vacuum pressure transmitted through the compression member 141. As vacuum pressure is applied to the vacuum pipe 130, the compression member 141 may pull the moving member 142. As the application of vacuum pressure to the vacuum pipe 130 is released, the compression member 141 may push the moving member 142. The moving member 142 may be disposed closer to the edge portion of the support part 110 than the compression member 141. The compression member 141 may be disposed closer to the central portion (e.g., in the x direction) of the support part 110 than the moving member 142. In an embodiment, the moving member 142 is movable within the vacuum pipe 130. The moving member 142 may move towards the central portion of the support part 110 within the vacuum pipe 130 by the pulling force of the compression member 141. The moving member 142 may move towards the edge portion of the support part 110 within the vacuum pipe 130 by the pushing force of the compression member 141. For example, in an embodiment, in area A, the moving member 142 may move in a +x direction as vacuum pressure is applied to the vacuum pipe 130, and the moving member 142 may move in a −x direction as the vacuum pressure in the vacuum pipe 130 is released.

In an embodiment, the fixing member 143 may be connected to (e.g., directly connected thereto) the moving member 142. In an embodiment, a distance between the fixing member 143 and the scrap area may be adjusted according to the moving direction of the moving member 142. For example, as the moving member 142 moves towards the central portion of the support part 110, the fixing member 143 may move closer to the scrap area. As the moving member 142 moves towards the edge portion of the support part 110, the fixing member 143 may move away from the scrap area. For example, in area A, the fixing member 143 may move closer to the scrap area as the moving member 142 moves in the +x direction, and it may move away from the scrap area as the moving member 142 moves in the −x direction.

Referring to FIG. 1, the fixing member 143 may directly contact the upper surface of the scrap area. However, embodiments of the present disclosure are not necessarily limited thereto. In some embodiments, the fixing member 143 may cover a portion of the upper surface of the scrap area without directly contacting the upper surface of the scrap area and may be spaced apart from the upper surface of the scrap area. For example, in an embodiment the fixing member 143 may come close to the scrap area so as to be spaced apart by a distance capable of preventing the scrap from being splashed by the cutting rotational force of the blade when the scrap area is cut.

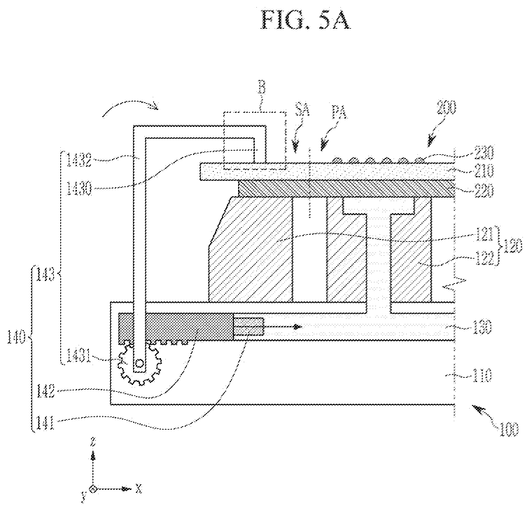

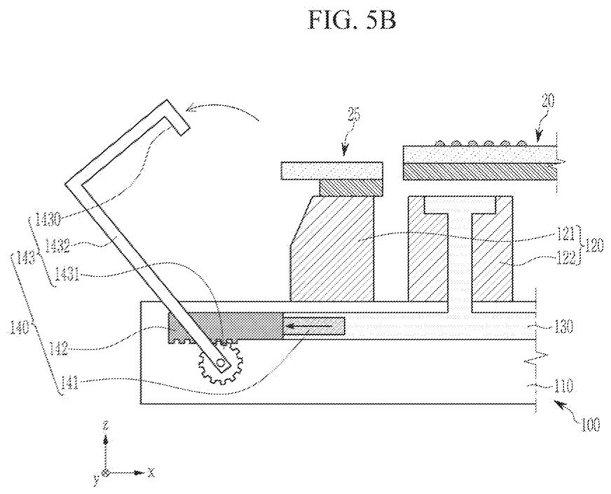

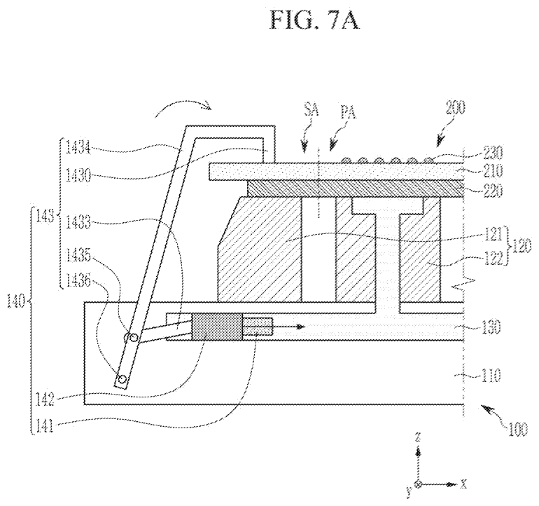

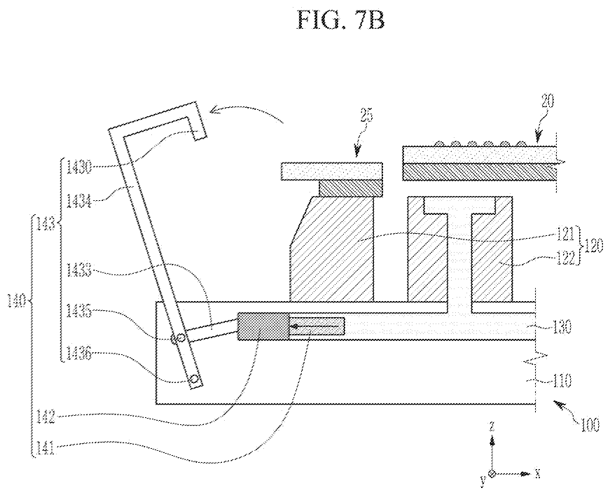

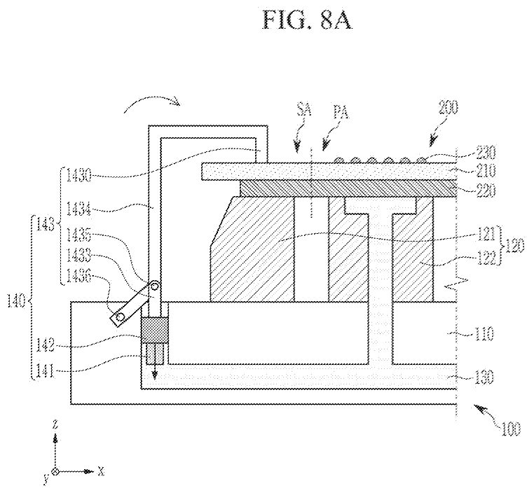

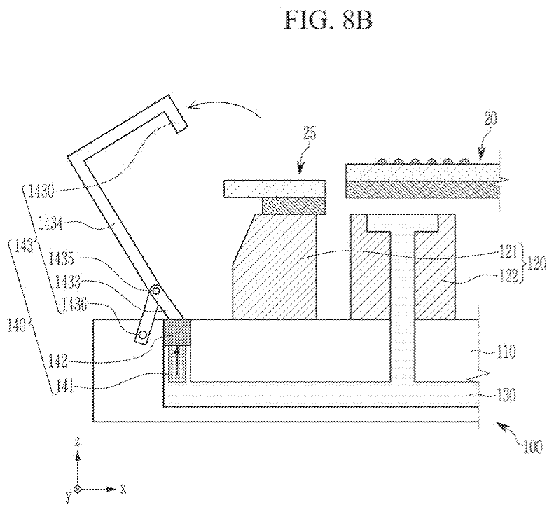

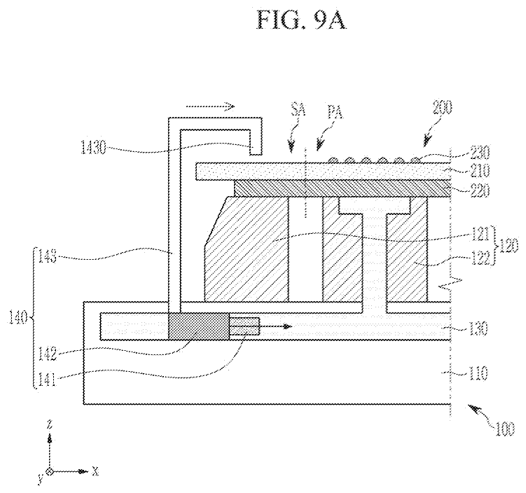

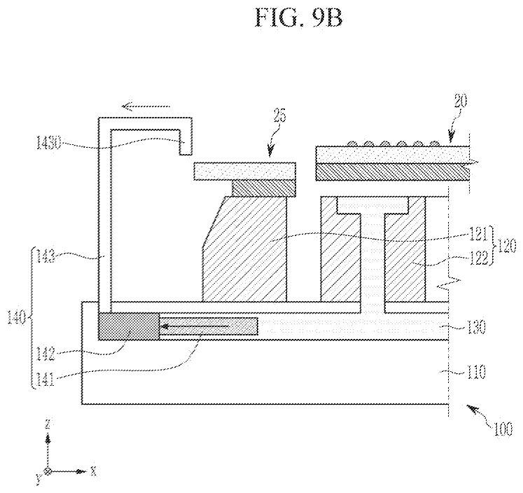

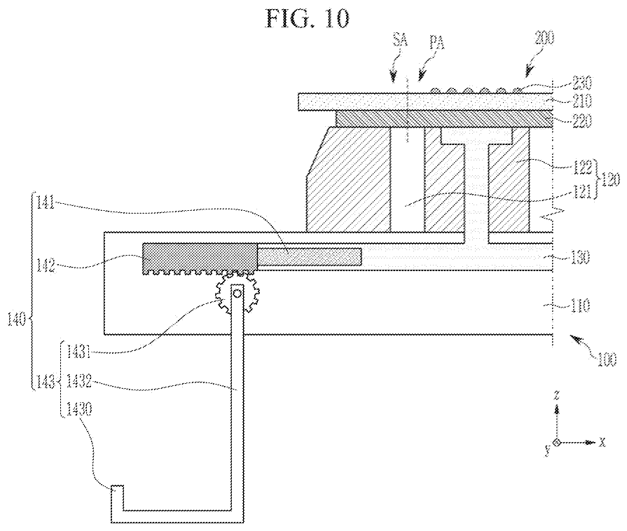

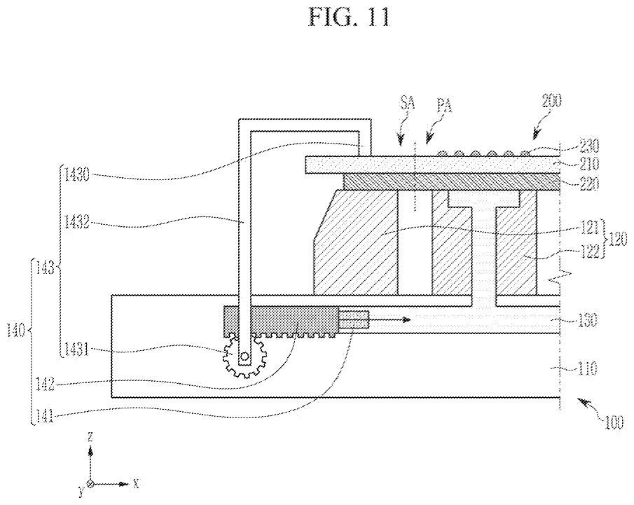

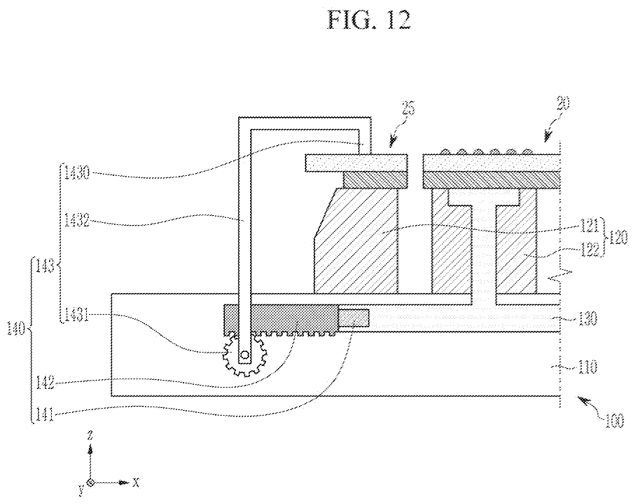

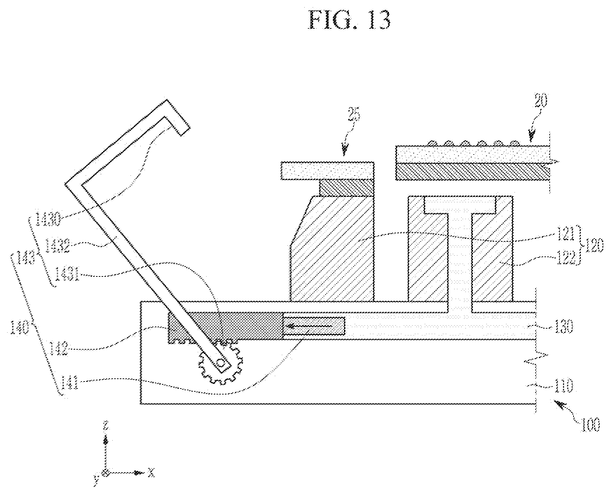

Referring to FIG. 1, the fixing device 140 of an embodiment may include a rack and pinion structure. However, embodiments of the present disclosure are not necessarily limited thereto, and various mechanical arrangements of the fixing device 140 that positions and fixes the scrap area by converting the vacuum pressure applied to the vacuum pipe 130 into another force that moves the fixing device 140 may be provided in some embodiments. Various embodiments of the fixing device 140 will be described later with reference to FIG. 5A, FIG. 5B, FIG. 7a, FIG. 7b, FIG. 8a, FIG. 8b, FIG. 9a, and FIG. 9b.

The chuck table 100 may include a plurality of fixing devices 140. The plurality of fixing devices 140 may be disposed to be spaced apart from each other along the scrap pad part 121 in a plan view. Each of the plurality of fixing devices 140 may fix each of the plurality of scrap pads.

According to an embodiment, since the fixing device 140 may fix the scrap area at the same time that vacuum pressure is applied to the vacuum pipe 130 so that the package area is vacuum-adsorbed, when the scrap area is cut, it is possible to prevent the solder ball 230 on the package substrate 200 from being damaged by the scrap being splashed by the cutting rotational force of the blade. To reduce damage to the solder ball 230, the volume of the scrap may be reduced by cutting the scrap area several times and splitting it finely. However, in this case, only the force to damage the solder ball 230 may be reduced, and the scrap still damages the solder ball 230, so it may not be an effective solution. On the other hand, by fixing the scrap area, the fixing device 140 according to an embodiment of the present disclosure may prevent the scrap from splashing towards the solder ball 230 when the scrap area is cut, thereby preventing damage itself. In addition, the fixing device 140 uses the same vacuum pressure applied through the vacuum pipe 130 to fix the package area without using a separate power, so that the package area and the scrap area may be fixed together when the vacuum pressure is applied to the same pipe, and the fixing of the package area and the scrap area together may be released when the vacuum pressure is released. Accordingly, it may be implemented only with a partial modification of the chuck table 100, and there is an advantage that there is no need to modify software or manufacturing facilities.

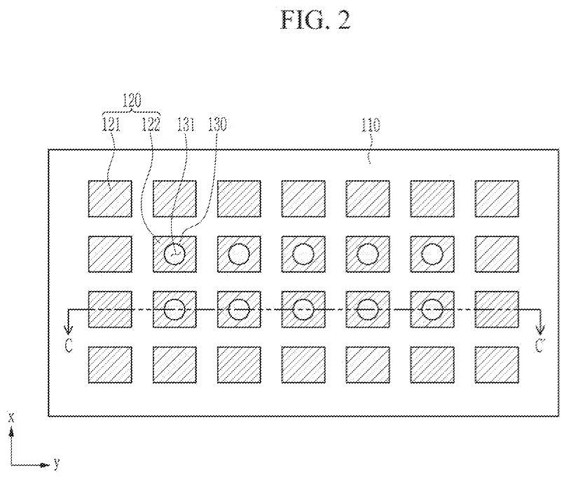

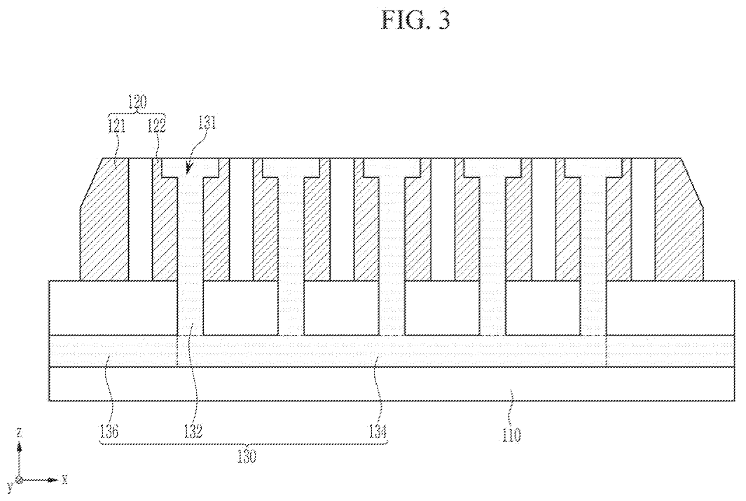

FIG. 2 illustrates a top plan view of the chuck table 100 of FIG. 1 viewed from above. FIG. 3 illustrates a cross-sectional view of the chuck table 100 of FIG. 1. In FIG. 2 and FIG. 3, the fixing device 140 is omitted to describe the pad part 120 and the vacuum pipe 130 of the chuck table 100 in more detail. FIG. 3 illustrates a cross-sectional view taken along line C-C′ of FIG. 2.

Referring to FIG. 2 and FIG. 3, the pad part 120 may be disposed on the support part 110. For example, the pad parts 120 may be disposed at regular intervals along the x direction and the y direction. The pad part 120 may include the package pad part 122 and the scrap pad part 121. The package pad part 122 may be a pad part that is positioned in the package area of the package substrate 200, and the scrap pad part 121 may be a pad part that is positioned in the scrap area of the package substrate 200.

Referring to FIG. 2, the package pad part 122 may be disposed in a central area of the support part 110 in a plan view (e.g., in the x and y directions). The scrap pad part 121 may be disposed on the edge area of the support part 110 so as to surround the package pad part 122 in a plan view (e.g., in the x and y directions).

The package pad part 122 may include a plurality of package pads. The scrap pad part 121 may include a plurality of scrap pads. The plurality of package pads, the plurality of scrap pads, and the package pad and the scrap pad adjacent to each other may be spaced apart from each other, respectively. During the sawing process, the blade may be inserted into a groove between the pads to cut the package substrate 200 placed on the pads. The gap between the pads may be thicker than the thickness of the blade.

In FIG. 2, the package pad part 122 is illustrated as including two package pads in the x direction and five package pads in the y direction. However, embodiments of the present disclosure are not necessarily limited thereto, and the package pad part 122 may include various numbers of package pads according to the sizes and shapes of the chuck table 100 and/or the package substrate 200. The scrap pad part 121 may include a number of scrap pads sufficient to surround the package pad part 122 according to the number of package pads in the package pad part 122.

In an embodiment, the package pad part 122 may include a through hole 131. In an embodiment, the scrap pad part 121 may not include the through hole 131. In an embodiment as shown in FIG. 2, a planar shape of the through hole 131 may be circular. However, embodiments of the present disclosure are not necessarily limited thereto. The vacuum pipe 130 may be disposed within the through hole 131. The vacuum pipe 130 may be formed to pass through the inside of the package pad part 122. The vacuum pipe 130 may not be formed to extend inside the scrap pad part 121.

Referring to FIG. 3, in an embodiment the through hole 131 may have a diameter of a portion adjacent to the upper surface of the package pad part 122 that is greater than a diameter of a portion adjacent to the lower surface of the package pad part 122 and a diameter of the middle portion of the package pad part 122 in the z direction. The upper surface of the package pad part 122 may be a surface in direct contact with the package substrate 200. The lower surface of the package pad part 122 may be a surface in direct contact with the support part 110.

In an embodiment, the vacuum pipe 130 may include a plurality of through-pipes 132 penetrating a plurality of package pads. The vacuum pipe 130 may include a connection pipe 134 connecting the plurality of through-pipes 132 to each other. The connection pipe 134 may connect portions in which the plurality of through-pipes 132 extend into the support part 110. For example, the connection pipe 134 may connect the plurality of through-pipes 132 in directions (e.g., the x and y directions) perpendicular to extending direction of the plurality of through-pipes 132. In an embodiment, a planar shape of the connection pipe 134 may have a mesh shape in which rows and columns are repeated in the x direction and the y direction. The connection pipe 134 may be formed in the central portion of the support part 110.

The vacuum pipe 130 may include an extension pipe 136 extending from the connection pipe 134 to the edge portion of the support part 110 (e.g., in the x and y directions). The central portion of the support part 110 may mean an area below the package pad part 122. The edge portion of the support part 110 may mean an area below the scrap pad part 121. The extension pipe 136 may extend into a portion of support part 110 disposed below the scrap pad 121.

As described above, the fixing device 140 of FIG. 1 may be connected to the vacuum pipe 130. In an embodiment, the fixing device 140 may be connected to (e.g., directly connected thereto) the extension pipe 136. The fixing device 140 may be disposed adjacent to the scrap pad part 121.

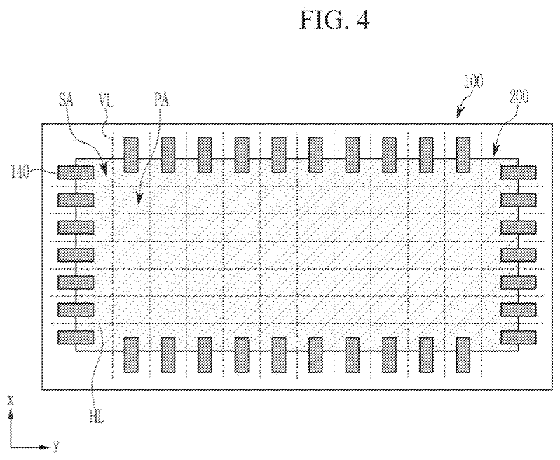

FIG. 4 illustrates a top plan view of the chuck table 100 of FIG. 1 viewed from above. FIG. 4 illustrates a state in which the package substrate 200 is placed on the support part 110 and the pad part 120 and in which a scrap area SA may be fixed by the fixing device 140.

Referring to FIG. 4, the chuck table 100 may include a plurality of fixing devices 140. For example, in an embodiment the chuck table 100 may include the same number of fixing devices 140 as the number of the scrap areas SA.

The package substrate 200 may include a plurality of package areas PA and a plurality of scrap area SA. The package area PA may mean an area that becomes a semiconductor package after the sawing process. The scrap area SA may mean an area that becomes a scrap after the sawing process. In an embodiment, the plurality of package areas PA may be arranged in a lattice form in the central portion of the package substrate 200. However, embodiments of the present disclosure are not necessarily limited thereto. The plurality of scrap areas SA may be disposed to surround the plurality of package areas PA on the edge portion of the package substrate 200 (e.g., in the x and y directions). The solder balls 230 may be disposed in the package area PA, but are omitted in FIG. 4 for convenience of explanation.

The plurality of fixing devices 140 may be disposed to be spaced apart from each other along the scrap pad part 121. In FIG. 4, one fixing device 140 is shown as fixing one scrap area SA. However, embodiments of the present disclosure are not necessarily limited thereto. As another example, one fixing device 140 may fix a plurality of scrap areas SA.

As vacuum pressure is applied to the vacuum pipe 130, the package area PA may be vacuum-adsorbed and fixed on the package pad part 122. As the vacuum pressure is applied to the vacuum pipe 130, the fixing device 140 may come closer to the upper surface of the scrap area SA. The fixing device 140 may overlap at least a portion of the upper surface of the scrap area SA in a plan view. For example, in an embodiment the fixing device 140 may directly contact the upper surface of the scrap area SA. However, embodiments of the present disclosure are not necessarily limited thereto. As another example, the fixing device 140 may fix the position of the scrap area SA in such a way that it does not directly contact the upper surface of the scrap area SA, maintains a gap, and prevents the scrap area SA from moving beyond a certain range from its original position.

In a state in which the vacuum pressure is applied to the vacuum pipe 130, the package substrate 200 may be cut along the sawing line. The sawing line may include a plurality of first lines VL extending in the x direction and a plurality of second lines HL extending in the y direction. The plurality of package areas PA and the plurality of scrap areas SA may be distinguished by the sawing line. When the package substrate 200 is cut along the sawing line by the blade, the package area PA becomes a semiconductor package, and the scrap area SA may become a scrap. For example, when the outermost lines (e.g., in the x and y directions) of the plurality of first line VL and of the plurality of second lines HL are cut, the plurality of fixing devices 140 fix the scrap areas SA, so that the scrap may be prevented from splashing toward the package area PA. Accordingly, the solder balls 230 disposed in the package area PA may not be damaged by the scrap.

In an embodiment, as at least one semiconductor package is separated from the package pad part 122, the vacuum pressure applied to the vacuum pipe 130 may be released. For example, as at least one semiconductor package singulated by the sawing process is lifted by a picker after the sawing process and separated from the package pad part 122, the vacuum pressure may be released. As the vacuum pressure releases, the package area PA is no longer vacuum-adsorbed, and the package area PA may be easily separated from the package pad part 122.

As the vacuum pressure in the vacuum pipe 130 is released, the fixing device 140 may move away from the upper surface of the scrap area SA. As the fixing device 140 moves away from the upper surface of the scrap area SA, the fixing device 140 may not overlap the upper surface of the scrap area SA in a plan view. As the fixing device 140 moves away from the upper surface of the scrap area SA, the fixing device 140 no longer fixes the scrap area SA, and the scrap area SA may be easily separated from the scrap pad part 121.

FIG. 5A and FIG. 5B illustrate enlarged views of area A of FIG. 1. The fixing device 140 of an embodiment will be described in more detail by enlarging the area A of FIG. 1. FIG. 5A may illustrate a state in which vacuum pressure is applied to the vacuum pipe 130. FIG. 5B may illustrate a state in which the vacuum pressure to the vacuum pipe 130 is released.

Referring to FIG. 5A, the package substrate 200 may be prepared on the chuck table 100. The chuck table 100 may include the support part 110, the pad part 120, the vacuum pipe 130, and the fixing device 140. The pad part 120 may be disposed on the support part 110, and the package substrate 200 may be placed on the pad part 120. In an embodiment, the package substrate 200 may include the substrate 210 on which a semiconductor chip is mounted, the molding member 220 covering the semiconductor chip mounted on the substrate 210, and the solder ball 230 attached to a surface facing (e.g., opposite thereto in the z direction) one surface of the substrate 210 covered by the molding member 220.

The package substrate 200 may include the package area PA and the scrap area SA surrounding the package area (e.g., in the x and y directions). The scrap area SA may be an edge area of the package substrate 200. The package area PA may be an area in which a semiconductor package including the substrate 210 on which a semiconductor chip is mounted, the molding member 220, and the solder ball 230 is disposed. The scrap area SA may include the substrate 210 and the molding member 220. The scrap area SA may not include semiconductor chips mounted on the substrate 210 and solder balls 230 attached thereto.

The pad part 120 may include the package pad part 122 directly contacting the package area PA and the scrap pad part 121 directly contacting the scrap area SA. The package pad part 122 and the scrap pad part 121 may be spaced apart from each other so that a blade may be inserted therebetween without making contact with the package pad part 122 or the scrap pad part 121.

The vacuum pipe 130 may pass through the package pad part 122 and extend into the support part 110. One side of the vacuum pipe 130 extending into the support part 110 through the package pad part 122 adjacent to the scrap pad part 121 may extend to an edge portion of the support part 110. The fixing device 140 may be connected to the vacuum pipe 130 extending to the edge portion of the support part 110.

In an embodiment, the fixing device 140 may include the compression member 141 compressed by vacuum pressure applied to the vacuum pipe 130. The compression member 141 may be disposed inside the vacuum pipe 130, and air may communicate with the inside of the vacuum pipe 130. In an embodiment, the compression member 141 may be compressed by vacuum pressure and may have a restoring force. In an embodiment, the compression member 141 may include, for example, a spring or a pneumatic cylinder. However, embodiments of the present disclosure are not necessarily limited thereto. For example, as the compression member 141 is compressed by the vacuum pressure, the x direction length of the compression member 141 thereof may be reduced.

The fixing device 140 may include the moving member 142 connected to the compression member 141. The moving member 142 may enter or exit the vacuum pipe by vacuum pressure transmitted through the compression member 141. In the vacuum pipe 130, the compression member 141 may be disposed closer to the central portion thereof (e.g., in the x direction) than the moving member 142. The compression member 141 may pull the moving member 142 towards the central portion of the support part 110 within the vacuum pipe 130. The moving member 142 may move toward the central portion of the support part 110 within the vacuum pipe 130 by the pulling force of the compression member 141. For example, in FIG. 5A, the moving member 142 may move in the +x direction.

The fixing device 140 may include the fixing member 143 connected to the moving member 142. A distance between the fixing member 143 and the scrap area SA may be adjusted according to the moving direction of the moving member 142. As shown in FIG. 5A, as the moving member 142 moves towards the central portion of the support part 110, the fixing member 143 may come closer to the scrap area. As shown in FIG. 5B, as the moving member 142 moves towards the edge portion of the support part 110, the fixing member 143 may move away from the scrap area.

In an embodiment, the moving member 142 may include a rack. In this embodiment, the fixing member 143 may include a pinion 1431 that rotates by being engaged with the rack and an arm 1432 that rotates by the rotation of the pinion 1431. For example, as the rack moves in the +x direction in FIG. 5A, the pinion 1431 may rotate clockwise. Accordingly, the arm 1432 connected to the pinion 1431 may rotate clockwise to come closer to the scrap area SA. As in the illustrated example, the arm 1432 may have a shape in which at least a portion thereof is bent.

In an embodiment, the fixing member 143 may include a fixing part 1430. The fixing part 1430 may refer to a portion closest to the upper surface of the scrap area SA among portions of the fixing member 143 in a state in which vacuum pressure is applied to the vacuum pipe 130. In the illustrated example, the fixing part 1430 may be connected to (e.g., directly connected thereto) the arm 1432. For example, the fixing part 1430 may be one end portion of the arm 1432. According to an embodiment, the fixing part 1430 may contact one surface of the scrap area SA, such as an upper surface of the scrap area SA.

Referring to FIG. 5A, as vacuum pressure is applied to the vacuum pipe 130, the package pad part 122 may vacuum-adsorb the package area PA. The package area PA may be fixed on the package pad part 122 by vacuum adsorption force. As vacuum pressure is applied to the vacuum pipe 130, the compression member 141 may be compressed in the x direction, the rack as the moving member 142 may move in the +x direction, and the pinion 1431 and the arm 1432 may rotate clockwise. As the arm 1432 rotates clockwise, the fixing part 1430 connected to the arm 1432 may be placed on the upper surface of the scrap area SA and press the upper surface of the scrap area SA in the −z direction. The scrap area SA may be fixed on the scrap pad part 121 by the force pressed by the fixing part 1430.

In the above embodiment, the fixing part 1430 may fix the scrap area SA by directly contacting the scrap area SA. However, embodiments of the present disclosure are not necessarily limited thereto. According to an embodiment, the fixing part 1430 may fix the scrap area SA without directly contacting one surface of the scrap area SA, such as the upper surface of the scrap area SA. For example, the fixing part 1430 may cover one surface of the scrap area SA in a spaced apart state. For example, the fixing part 1430 may hover above the upper surface of the scrap area SA. When the scrap area SA is cut, the fixing part 1430 may maintain a space sufficient to prevent the cut scrap area SA from splashing toward the package area PA, and may fix the position of the scrap area SA.

The sawing (e.g., singulation) process may proceed in the state of FIG. 5A. The package substrate 200 may be cut by a blade. The blade may cut the package substrate 200 along sawing lines positioned between adjacent package areas PA, between adjacent scrap areas SA, and between adjacent package areas PA and scrap areas SA.

Referring to FIG. 5B, by the sawing process, the scrap area SA in FIG. 5A may become a scrap 25, and the package area PA in FIG. 5A may become a semiconductor package 20. According to an embodiment, as the semiconductor package 20 is picked up after the sawing process, the vacuum pressure to the vacuum pipe 130 may be released. For example, in an embodiment a picker may separate the semiconductor package 20 from the package pad part 122.

As the vacuum pressure to the vacuum pipe 130 is released, the compression of the compression member 141 compressed in the vacuum state may be released. For example, in FIG. 5B, the length of the compression member 141 may increase in the x direction to be restored to its original length. As compression is released, the compression member 141 may push the moving member 142 in the −x direction. As the moving member 142, which is the rack, moves in the −x direction, the pinion 1431 and the arm 1432 may rotate counterclockwise. As the arm 1432 rotates counterclockwise, the fixing part 1430 connected to (e.g., directly connected thereto) the arm 1432 may move away from the scrap area SA.

The moving direction of the moving member 142 and the rotating directions of the pinion 1431 and the arm 1432 described above are directions applied to the fixing device 140 at a position corresponding to the area A of FIG. 1 among the plurality of fixing devices 140 included in the chuck table 100, and the moving direction of the fixing device 140 at another position may be different from the direction described above.

FIG. 6 illustrates an enlarged view of area B of FIG. 5A. FIG. 6 is a drawing for explaining the fixing part 1430 in more detail.

Referring to FIG. 6, the fixing part 1430 may be connected to (e.g., directly connected thereto) the arm 1432. The fixing part 1430 may be connected to the arm 1432 in a tilting manner. According to an embodiment, the fixing part 1430 may be capable of tilting. For example, the fixing part 1430 may be tilted to be vertically disposed on the substrate 210 corresponding to the scrap area SA, regardless of the angle of the arm 1432 with respect to the scrap area SA. Accordingly, the fixing part 1430 may directly contact the substrate 210 in the vertical direction (−z direction in FIG. 5A), and it may press the scrap area SA in the vertical direction, so that the scrap area SA may be stably fixed.

In an embodiment, the fixing part 1430 may include a contact portion 1430a that includes a contact surface directly contacting the upper surface of the scrap area SA and a portion adjacent to the contact surface. In an embodiment, the contact portion 1430a of the fixing part 1430 may include a material having elasticity. For example, the contact portion 1430a may be made of rubber. However, embodiments of the present disclosure are not necessarily limited thereto, and any other material that does not damage the surface of the substrate 210 may be utilized for the contact portion 1430a.

According to an embodiment, the contact portion 1430a of the fixing part 1430 may have a round shape. However, embodiments of the present disclosure are not necessarily limited thereto. For example, in an embodiment in which the contact portion 1430a has a round shape, the force pressing the substrate 210 may be evenly distributed over the contact surface. In this embodiment, the contact surface of the contact portion 1430a may be a curved surface.

Hereinafter, variations of the fixing device 140 will be described with reference to FIG. 7A, FIG. 7B, FIG. 8A, FIG. 8B, FIG. 9A, and FIG. 9B, and differences from the fixing device 140 shown in FIG. 5A and FIG. 5B will be mainly described. Redundant descriptions may be replaced with descriptions referring to FIG. 5A and FIG. 5B and may not be repeated for economy of description.

FIG. 7A and FIG. 7B respectively illustrate a fixing device 140 according to an embodiment. FIG. 7A and FIG. 7B respectively illustrate an enlarged view of an area corresponding to the area A of FIG. 1 in a chuck table 100 including the fixing device 140 of an embodiment. FIG. 7A may illustrate a state in which vacuum pressure is applied to the vacuum pipe 130. FIG. 5B may illustrate a state in which the vacuum pressure to the vacuum pipe 130 is released.

Referring to FIG. 7A, the vacuum pipe 130 may pass through the package pad part 122 and extend into the support part 110. One side of the vacuum pipe 130 extending into the support part 110 through the package pad part 122 adjacent to the scrap pad part 121 may extend to an edge portion of the support part 110. The fixing device 140 may be connected to the vacuum pipe 130 extending to the edge portion of the support part 110.

The fixing device 140 may include the compression member 141 that is disposed inside the vacuum pipe 130 and compressed by vacuum pressure applied to the vacuum pipe 130. For example, as the compression member 141 is compressed by the vacuum pressure, the x direction length thereof may be reduced.

The fixing device 140 may include the moving member 142 that is connected to the compression member 141 and enters or exits the vacuum pipe by vacuum pressure transmitted through the compression member 141. In the vacuum pipe 130, the compression member 141 may be disposed closer to the central portion thereof than the moving member 142. The compression member 141 may pull the moving member 142 towards the central portion of the support part 110 within the vacuum pipe 130. The moving member 142 may move towards the central portion of the support part 110 within the vacuum pipe 130 by the pulling force of the compression member 141. For example, in FIG. 5A, the moving member 142 may move in the +x direction within the vacuum pipe 130.

The fixing device 140 may include the fixing member 143 that is connected to the moving member 142 and has a distance from the scrap area SA adjusted according to the moving direction of the moving member 142. In an embodiment, as the moving member 142 moves towards the central portion of the support part 110, the fixing member 143 may come closer to the scrap area. As the moving member 142 moves towards the edge portion of the support part 110, the fixing member 143 may move away from the scrap area.

In an embodiment as shown in FIGS. 7A and 7B, the fixing member 143 may include a first link 1434 rotatably connected to the support part 110 and a second link 1433 rotatably connected to the first link 1434 and the moving member 142. For example, the first link 1434 and the second link 1433 may be connected (e.g., directly connected) by a first fixing pin 1435. For example, the first link 1434 and the support part 110 may be connected (e.g., directly connected) by a second fixing pin 1436. The second link 1433 and the first link 1434 may rotate by the movement of the moving member 142.

For example, as the moving member 142 moves in the +x direction in FIG. 7A, the moving member 142 may pull the second link 1433 in the +x direction. The second link 1433 may transmit a pulling force in the +x direction to the first link 1434 through the first fixing pin 1435 connected to the first link 1434. The first link 1434 may rotate clockwise around the second fixing pin 1436 connected to the support part 110 by the force transmitted from the second link 1433. Accordingly, the first link 1434 rotates clockwise, and the first link 1434 including the fixing part 1430 may come closer to the scrap area SA. As in the illustrated example, the first link 1434 may have a shape in which at least a portion thereof is bent.

The fixing member 143 may include the fixing part 1430. The fixing part 1430 may refer to a portion closest to the upper surface of the scrap area SA among portions of the fixing member 143 in a state in which vacuum pressure is applied to the vacuum pipe 130. In the illustrated example shown in FIGS. 7A and 7B, the fixing part 1430 may be connected to (e.g., directly connected thereto) the first link 1434. For example, the fixing part 1430 may be one end portion of the first link 1434. The fixing part 1430 may contact one surface of the scrap area SA, such as an upper surface of the scrap area SA, or may cover one surface of the scrap area SA in a spaced apart state (e.g., hover) without directly contacting the one surface of the scrap area SA. The following description assumes that the fixing part 1430 directly contacts the upper surface of the scrap area SA for convenience of description.

Referring to FIG. 7A, as vacuum pressure is applied to the vacuum pipe 130, the package pad part 122 may vacuum-adsorb the package area PA. The package area PA may be fixed on the package pad part 122 by vacuum adsorption force. As vacuum pressure is applied to the vacuum pipe 130, the compression member 141 may be compressed in the x direction, the moving member 142 may move in the +x direction, and the second link 1433 may transmit a force pulled by the moving member 142 in the +x direction to the first link 1434 through the first fixing pin 1435 connected to the first link 1434. The first link 1434 may rotate clockwise around the second fixing pin 1436 connected to the support part 110 by the transmitted force. As the first link 1434 rotates clockwise, the fixing part 1430 connected to the first link 1434 may be disposed directly on the upper surface of the scrap area SA and press the upper surface of the scrap area SA in the −z direction. The scrap area SA may be fixed on the scrap pad part 121 by the force pressed by the fixing part 1430.

The sawing process may proceed in the state of FIG. 7A. The package substrate 200 may be cut by a blade. The blade may cut the package substrate 200 along sawing lines positioned between adjacent package areas PA, between adjacent scrap areas SA, and between adjacent package areas PA and scrap areas SA.

Referring to FIG. 7B, by the sawing process, the scrap area SA in FIG. 7A may become a scrap 25, and the package area PA in FIG. 7A may become a semiconductor package 20. According to an embodiment, as the semiconductor package 20 is picked up after the sawing process, the vacuum pressure to the vacuum pipe 130 may be released. For example, a picker may separate the semiconductor package 20 from the package pad part 122.

As the vacuum pressure to the vacuum pipe 130 is released, the compression of the compression member 141 compressed in the vacuum state may be released. For example, in FIG. 7B, the length of the compression member 141 may increase in the +x direction to be restored to its original length. As compression is released, the compression member 141 may push the moving member 142 in the −x direction. As the moving member 142 moves in the −x direction, the second link 1433 may transmit a pushing force of the moving member 142 in the −x direction to the first link 1434 through the first fixing pin 1435 connected to the first link 1434. The first link 1434 may rotate counterclockwise around the second fixing pin 1436 connected to the support part 110 by the transmitted force. As the first link 1434 rotates counterclockwise, the fixing part 1430 connected to the first link 1434 may move away from the scrap area SA.

The moving direction of the moving member 142 and the rotating direction of the first link 1434 and the second link 1433 described above are directions applied to the fixing device 140 at a position corresponding to the area A of FIG. 1 among the plurality of fixing devices 140 included in the chuck table 100, and the moving direction of the fixing device 140 at another position may be different from the direction described above.

FIG. 8A and FIG. 8B respectively illustrate a fixing device 140 according to an embodiment. The embodiment shown in FIG. 8A and FIG. 8B is similar to the embodiment shown in FIG. 7A and FIG. 7B, but they differ in the direction of force. FIG. 8A and FIG. 8B respectively illustrate an enlarged view of an area corresponding to the area A of FIG. 1 in a chuck table 100 including the fixing device 140 of an embodiment. FIG. 8A may illustrate a state in which vacuum pressure is applied to the vacuum pipe 130. FIG. 8B may illustrate a state in which the vacuum pressure to the vacuum pipe 130 is released.

Referring to FIG. 8A, the vacuum pipe 130 may pass through the package pad part 122 and extend into the support part 110. One side of the vacuum pipe 130 extending into the support part 110 through the package pad part 122 adjacent to the scrap pad part 121 may extend to an edge portion of the support part 110. In an embodiment shown in FIGS. 8A and 8B, the vacuum pipe 130 extending to the edge portion of the support part 110 may be bent toward the upper surface of the support part 110. For example, the vacuum pipe 130 extending to the edge portion of the support part 110 may include a portion extending in the x direction and a portion extending in the z direction. The fixing device 140 may be connected to the portion extending in the z direction of the vacuum pipe 130 extending to the edge portion of the support part 110.

The fixing device 140 may include the compression member 141 that is disposed inside the vacuum pipe 130 and compressed by vacuum pressure applied to the vacuum pipe 130. For example, as the compression member 141 is compressed by the vacuum pressure, the z direction length thereof may be reduced.

The fixing device 140 may include the moving member 142 that is connected to the compression member 141 and enters or exits the vacuum pipe by vacuum pressure transmitted through the compression member 141. In the vacuum pipe 130, the compression member 141 may be disposed closer to the central portion thereof (e.g., in the z direction) than the moving member 142. The compression member 141 may pull the moving member 142 towards the central portion of the support part 110 within the vacuum pipe 130. The moving member 142 may move towards the central portion (e.g., in the z direction) of the support part 110 within the vacuum pipe 130 by the pulling force of the compression member 141. For example, in FIG. 8A, the moving member 142 may move in the −z direction within the vacuum pipe 130.

The fixing device 140 may include the fixing member 143 that is connected to (e.g., directly connected thereto) the moving member 142 and has a distance from the scrap area SA adjusted according to the moving direction of the moving member 142. As the moving member 142 moves towards the central portion of the support part 110, the fixing member 143 may come closer to the scrap area. As the moving member 142 moves towards the edge portion of the support part 110, the fixing member 143 may move away from the scrap area.

In an embodiment as shown in FIGS. 8A and 8B, the fixing member 143 may include a first link 1434 rotatably connected to the support part 110 and a second link 1433 rotatably connected to the first link 1434 and the moving member 142. For example, the first link 1434 and the second link 1433 may be connected (e.g., directly connected) by a first fixing pin 1435. For example, the first link 1434 and the support part 110 may be connected by a second fixing pin 1436. The second link 1433 and the first link 1434 may rotate by the movement of the moving member 142.

For example, as the moving member 142 moves in the −z direction in FIG. 8A, the moving member 142 may pull the second link 1433 in the −z direction. The second link 1433 may transmit a pulling force in the −z direction to the first link 1434 through the first fixing pin 1435 connected to the first link 1434. The first link 1434 may rotate clockwise around the second fixing pin 1436 connected to the support part 110 by the force transmitted from the second link 1433. Accordingly, the first link 1434 rotates clockwise, and may come closer to the scrap area SA. In an embodiment, as shown in FIGS. 8A and 8B, the first link 1434 may have a shape in which at least a portion thereof is bent.

The fixing member 143 may include the fixing part 1430. The fixing part 1430 may refer to a portion closest to the upper surface of the scrap area SA among portions of the fixing member 143 in a state in which vacuum pressure is applied to the vacuum pipe 130. In an embodiment shown in FIGS. 8A and 8B, the fixing part 1430 may be connected to (e.g., directly connected thereto) the first link 1434. For example, the fixing part 1430 may be one end portion of the first link 1434. In an embodiment, the fixing part 1430 may directly contact one surface of the scrap area SA, or may cover (e.g., hover over) one surface of the scrap area SA in a spaced apart state without directly contacting the one surface of the scrap area SA. The following description assumes that the fixing part 1430 directly contacts the upper surface of the scrap area SA for convenience of explanation.

Referring to FIG. 8A, as vacuum pressure is applied to the vacuum pipe 130, the package pad part 122 may vacuum-adsorb the package area PA. The package area PA may be fixed on the package pad part 122 by vacuum adsorption force. As vacuum pressure is applied to the vacuum pipe 130, the compression member 141 may be compressed in the z direction, the moving member 142 may move in the −z direction, and the second link 1433 may transmit a force pulled by the moving member 142 in the −z direction to the first link 1434 through the first fixing pin 1435 connected to the first link 1434. The first link 1434 may rotate clockwise around the second fixing pin 1436 connected to the support part 110 by the transmitted force. As the first link 1434 rotates clockwise, the fixing part 1430 connected to the first link 1434 may directly contact the upper surface of the scrap area SA and press the upper surface of the scrap area SA in the −z direction. The scrap area SA may be fixed on the scrap pad part 121 by the force pressed by the fixing part 1430.

The sawing process may proceed in the state of FIG. 8A. The package substrate 200 may be cut by a blade. The blade may cut the package substrate 200 along sawing lines positioned between adjacent package areas PA, between adjacent scrap areas SA, and between adjacent package areas PA and scrap areas SA. Referring to FIG. 8B, by the sawing process, the scrap area SA in FIG. 8A

may become a scrap 25, and the package area PA in FIG. 8A may become a semiconductor package 20. According to an embodiment, as the semiconductor package 20 is picked up after the sawing process, the vacuum pressure to the vacuum pipe 130 may be released. For example, in an embodiment a picker may separate the semiconductor package 20 from the package pad part 122.

As the vacuum pressure to the vacuum pipe 130 is released, the compression of the compression member 141 compressed in the vacuum state may be released. For example, in FIG. 8B, the length of the compression member 141 may increase in the +z direction to be restored to its original length. As compression is released, the compression member 141 may push the moving member 142 in the +z direction. As the moving member 142 moves in the +z direction, the second link 1433 may transmit a pushing force of the moving member 142 in the +z direction to the first link 1434 through the first fixing pin 1435 connected to the first link 1434. The first link 1434 may rotate counterclockwise around the second fixing pin 1436 connected to the support part 110 by the transmitted force. As the first link 1434 rotates counterclockwise, the fixing part 1430 connected to the first link 1434 may move away from the scrap area SA.

The moving direction of the moving member 142 and the rotating direction of the first link 1434 and the second link 1433 described above are directions applied to the fixing device 140 at a position corresponding to the area A of FIG. 1 among the plurality of fixing devices 140 included in the chuck table 100, and the moving direction of the fixing device 140 at another position may be different from the direction described above.

FIG. 9A and FIG. 9B respectively illustrate a fixing device 140 according to an embodiment. FIG. 9A and FIG. 9B respectively illustrate an enlarged view of an area corresponding to the area A of FIG. 1 in a chuck table 100 including the fixing device 140 of an embodiment. FIG. 9A may illustrate a state in which vacuum pressure is applied to the vacuum pipe 130. FIG. 9B may illustrate a state in which the vacuum pressure to the vacuum pipe 130 is released.

Referring to FIG. 9A, the vacuum pipe 130 may pass through the package pad part 122 and extend into the support part 110. One side of the vacuum pipe 130 extending into the support part 110 through the package pad part 122 adjacent to the scrap pad part 121 may extend to an edge portion of the support part 110. The fixing device 140 may be connected to the vacuum pipe 130 extending to the edge portion of the support part 110.

The fixing device 140 may include the compression member 141 that is disposed inside the vacuum pipe 130 and compressed by vacuum pressure applied to the vacuum pipe 130. For example, as the compression member 141 is compressed by the vacuum pressure, the x direction length thereof may be reduced.

The fixing device 140 may include the moving member 142 that is connected to the compression member 141 and enters or exits the vacuum pipe by vacuum pressure transmitted through the compression member 141. In the vacuum pipe 130, the compression member 141 may be disposed closer to the central portion thereof (e.g., in the x direction) than the moving member 142. The compression member 141 may pull the moving member 142 towards the central portion of the support part 110 within the vacuum pipe 130. The moving member 142 may move toward the central portion of the support part 110 within the vacuum pipe 130 by the pulling force of the compression member 141. For example, in FIG. 9A, the moving member 142 may move in the +x direction within the vacuum pipe 130.

The fixing device 140 may include the fixing member 143 that is connected to the moving member 142 and has a distance from the scrap area SA adjusted according to the moving direction of the moving member 142. As the moving member 142 moves towards the central portion of the support part 110, the fixing member 143 may come closer to the scrap area. As the moving member 142 moves towards the edge portion of the support part 110, the fixing member 143 may move away from the scrap area.

In the embodiments described above with reference to FIG. 5A, FIG. 5B, FIG. 7A, FIG. 7B, FIG. 8A, and FIG. 8B, the fixing member 143 may rotate by the linear motion of the moving member 142, and the fixing member 143 may rotate in a direction corresponding to the moving direction of the moving member 142. In an embodiment shown in FIG. 9A and FIG. 9B to be described later, the fixing member 143 may linearly move (e.g., in the x direction) by the linear motion of the moving member 142.

In an embodiment shown in FIGS. 9A-9B, the fixing member 143 may linearly move in a direction parallel to the moving direction of the moving member 142. For example, as the moving member 142 moves in the +x direction in FIG. 9A, the moving member 142 may pull the fixing member 143 in the +x direction. Accordingly, the fixing member 143 may move in the +x direction to come closer to the scrap area SA. As in the illustrated example, the fixing member 143 may have a shape in which at least a portion thereof is bent.

The fixing member 143 may include the fixing part 1430. The fixing part 1430 may refer to a portion closest to the upper surface of the scrap area SA among portions of the fixing member 143 in a state in which vacuum pressure is applied to the vacuum pipe 130. For example, in an embodiment the fixing part 1430 may be one end portion of the fixing member 143. The fixing part 1430 may contact one surface of the scrap area SA, such as the upper surface of the scrap area SA, or may cover (e.g., hover over) one surface of the scrap area SA in a spaced apart state without directly contacting the one surface of the scrap area SA. The following description assumes that the fixing part 1430 is spaced apart from the upper surface of the scrap area SA in the z direction for convenience of explanation.

Referring to FIG. 9A, as vacuum pressure is applied to the vacuum pipe 130, the package pad part 122 may vacuum-adsorb the package area PA. The package area PA may be fixed on the package pad part 122 by vacuum adsorption force. As vacuum pressure is applied to the vacuum pipe 130, the compression member 141 may be compressed in the +x direction, the moving member 142 may move in the +x direction, and the moving member 142 may transmit a pulling force in the +x direction to the fixing member 143. The fixing member 143 may move in the +x direction by the transmitted force. As the fixing member 143 moves in the +x direction, the fixing part 1430 may be placed over the upper surface of the scrap area SA and overlap the upper surface of the scrap area SA while being spaced apart from the upper surface of the scrap area SA in the z direction. The scrap area SA may be fixed on the scrap pad part 121 by the fixing part 1430 so as not to deviate more than a certain range from the position on the scrap pad part 121. For example, when the scrap area SA is cut, the fixing part 1430 may prevent the cut scrap area SA from splashing toward the package area PA.

The sawing process may proceed in the state of FIG. 9A. The package substrate 200 may be cut by a blade. The blade may cut the package substrate 200 along sawing lines positioned between adjacent package areas PA, between adjacent scrap areas SA, and between adjacent package areas PA and scrap areas SA.

Referring to FIG. 9B, by the sawing process, the scrap area SA in FIG. 9A may become a scrap 25, and the package area PA in FIG. 9A may become a semiconductor package 20. According to an embodiment, as the semiconductor package 20 is picked up after the sawing process, the vacuum pressure to the vacuum pipe 130 may be released. For example, in an embodiment a picker may separate the semiconductor package 20 from the package pad part 122.

As the vacuum pressure to the vacuum pipe 130 is released, the compression of the compression member 141 compressed in the vacuum state may be released. For example, in FIG. 9B, the length of the compression member 141 may increase in the +x direction to be restored to its original length. As compression is released, the compression member 141 may push the moving member 142 in the −x direction. As the moving member 142 moves in the −x direction, the moving member 142 may transmit a pushing force in the −x direction to the fixing member 143. The fixing member 143 may move in the −x direction by the transmitted force. As the fixing member 143 moves in the −x direction, the fixing part 1430 may move away from the scrap area SA in a linear direction (e.g., the −x direction).

The moving directions of the moving member 142 and the fixing member 143 described above are directions applied to the fixing device 140 at a position corresponding to the area A of FIG. 1 among the plurality of fixing devices 140 included in the chuck table 100, and the moving direction of the fixing device 140 at another position may be different from the direction described above.

FIG. 10 to FIG. 13 are drawings of a semiconductor package manufacturing method using the chuck table 100 according to embodiments of the present disclosure. FIG. 10 to FIG. 13 illustrate enlarged views of the area A of FIG. 1 at respective steps. The semiconductor package manufacturing method shown in FIG. 10 to FIG. 13 may be a semiconductor package manufacturing method using the chuck table 100 of an embodiment shown in FIG. 5A and FIG. 5B.

Referring to FIG. 10, the chuck table 100 may include the support part 110, the pad part 120, the vacuum pipe 130, and the fixing device 140. The pad part 120 may be disposed on the support part 110 (e.g., disposed directly thereon). In an embodiment, the pad part 120 may include the package pad part 122 in direct contact with the package area PA of the package substrate 200 and the scrap pad part 121 in direct contact with the scrap area SA of the package substrate 200. The package pad part 122 may be disposed in a central area (e.g., in the x and y directions) of the support part 110 in a plan view. The scrap pad part 121 may be disposed on the edge area of the support part 110 so as to surround the package pad part 122 in a plan view.

In an embodiment, the package pad part 122 may include a plurality of package pads, and the scrap pad part 121 may include a plurality of scrap pads. In an embodiment, the plurality of package pads may be repeatedly arranged in the x direction and the y direction in a matrix form. The plurality of scrap pads may be arranged in a line shape extending in the x direction and the y direction at one side of the outermost package pads among the plurality of package pads.

The plurality of package pads, the plurality of scrap pads, and the package pad and the scrap pads adjacent to each other may be respectively spaced apart from each other by a distance at which a blade cutting the package substrate 200 may be inserted without contacting the package pad or scrap pad.

The vacuum pipe 130 may pass through the package pad part 122 to extend into the support part 110. In an embodiment, the vacuum pipe 130 may pass through the package pad part 122 in the z direction. The vacuum pipe 130 extending into the support part 110 may extend in the x direction. One side of the vacuum pipe 130 extending into the support part 110 may be connected to a portion of the vacuum pipe 130 extending into the support part 110 through an adjacent package pad. The other side of the vacuum pipe 130 extending into the support part 110 may extend to an edge portion of the support part 110. The fixing device 140 may be connected to the vacuum pipe 130 extending to the edge portion of the support part 110.

The fixing device 140 may be connected to the vacuum pipe 130 extending to the edge portion of the support part 110, and may be disposed adjacent to the scrap pad part 121. In an embodiment, the fixing device 140 may include the compression member 141, the moving member 142, and the fixing member 143. The compression member 141 may be disposed inside the vacuum pipe 130, and air may communicate with the inside of the vacuum pipe 130. The compression member 141 may be compressed by vacuum pressure applied to the vacuum pipe 130. In an embodiment, the compression member 141 may have a restoring force. A length of the compression member 141 may be reduced as it is compressed by the vacuum pressure, and may be restored to its original length as the vacuum pressure is removed. In an embodiment, the compression member 141 may include, for example, a spring or a pneumatic cylinder. However, embodiments of the present disclosure are not necessarily limited thereto.

The moving member 142 is connected to the compression member 141, and may enter or exit the vacuum pipe 130 by vacuum pressure transmitted through the compression member 141. The moving member 142 may be disposed closer to the edge portion of the support part 110 than the compression member 141. As vacuum pressure is applied to the vacuum pipe 130, the compression member 141 may pull the moving member 142 (e.g., away from the edge portion of the support part 110). As the application of vacuum pressure to the vacuum pipe 130 is released, the compression member 141 may push the moving member 142 (e.g., towards the edge portion of the support part 110). The moving member 142 may move towards the central portion of the support part 110 within the vacuum pipe 130 by the pulling force of the compression member 141. The moving member 142 may move towards the edge portion of the support part 110 within the vacuum pipe 130 by the pushing force of the compression member 141.

The fixing member 143 may be connected to the moving member 142. A distance between the fixing member 143 and the scrap area may be adjusted according to the moving direction of the moving member 142. As the moving member 142 moves towards the central portion of the support part 110, the fixing member 143 may come closer to the scrap area. As the moving member 142 moves toward the edge portion of the support part 110, the fixing member 143 may move away from the scrap area.

In an embodiment shown in FIG. 10, the moving member 142 may include a rack, and the fixing member 143 may include the pinion 1431 that rotates while engaging with the rack and the arm 1432 that rotates by rotation of the pinion 1431. The arm 1432 may have a shape in which at least a portion thereof is bent. For example, as the rack moves in the +x direction, the pinion 1431 may rotate clockwise. Accordingly, the arm 1432 connected to the pinion 1431 may rotate clockwise to come closer to the scrap area SA. As the rack moves in the −x direction, the pinion 1431 may rotate counterclockwise. Accordingly, the arm 1432 connected to the pinion 1431 may rotate counterclockwise to come closer to the scrap area SA.

The fixing member 143 may include the fixing part 1430. The fixing part 1430 may refer to a portion closest to the scrap area SA when the fixing member 143 is close to the scrap area SA. In an embodiment, the fixing part 1430 may refer to a portion directly contacting the scrap area SA when the fixing member 143 is close to the scrap area SA. In FIG. 10, the fixing part 1430 may be connected to the arm 1432 (e.g., directly connected thereto). For example, the fixing part 1430 may be one end portion of the arm 1432.

Referring to FIG. 10, the package substrate 200 including the package area PA in which a plurality of semiconductor packages are arranged and the scrap area SA surrounding the package area PA may be prepared. In an embodiment, the package substrate 200 may include a substrate 210 on which a semiconductor chip is mounted, a molding member 220 covering the semiconductor chip mounted on the substrate 210, and a solder ball 230 attached to a surface facing one surface of the substrate 210 covered by the molding member 220 (e.g., a surface of the substrate 210 opposite in the z direction to the surface having the molding member 220 disposed directly thereon).

The package area PA may be an area in which a semiconductor package including the substrate 210 on which a semiconductor chip is mounted, the molding member 220, and the solder ball 230 is disposed. For example, the package substrate 200 may include a plurality of semiconductor packages in the form of a lattice that is repeatedly arranged in an x direction and a y direction. The package area may mean an area that becomes a semiconductor package after the sawing process. The scrap area SA may include the substrate 210 and the molding member 220. The scrap area SA may not include a semiconductor chip mounted on the substrate 210 or a solder ball 230 attached thereto. The scrap area may mean an area that becomes a scrap after the sawing process. The scrap may be a scrap portion of the package substrate 200 on which a semiconductor chip is not mounted on the substrate 210. The scrap may include only the substrate 210 and the molding member 220 without semiconductor chips.

A semiconductor package manufacturing apparatus including the chuck table 100 may position the package substrate 200 on the chuck table 100. The package substrate 200 may be disposed on the pad part 120 so that the molding member 220 faces downwardly in the z direction towards the support part 110. The package area PA of the package substrate 200 may be placed on the package pad part 122, and the scrap area SA of the package substrate 200 may be placed on the scrap pad part 121. The vacuum pipe 130 may directly contact the package area PA of the package substrate 200 through the upper surface of the package pad part 122.

In an embodiment, at least a portion of the vacuum pipe 130 may be connected to a vacuum source that generates vacuum pressure. The vacuum pipe 130 shown in FIG. 10 may be in a state before vacuum pressure is applied thereto. Before the vacuum pressure is applied to the vacuum pipe 130, the package area PA is not adsorbed to the package pad part 122, and the fixing device 140 may be disposed farthest from the scrap area SA.

Referring to FIG. 11, a vacuum source may apply vacuum pressure to the vacuum pipe 130. As the vacuum pressure is applied to the vacuum pipe 130, the package area PA may be vacuum-adsorbed to the package pad part 122. As the vacuum pressure is applied to the vacuum pipe 130, the fixing device 140 may come closer to the upper surface of the scrap area SA.

When the vacuum pressure is applied to the vacuum pipe 130, the compression member 141 may be compressed. For example, the compression member 141 may be compressed in the x direction. The compression member 141 that is compressed may pull the moving member 142 in the +x direction.

The moving member 142 may move in the +x direction within the vacuum pipe 130 by the pulling force of the compression member 141. For example, the moving member 142 that is a rack may move in the +x direction.

The fixing member 143 connected to the moving member 142, including the fixing part 1430, may come closer to the upper surface of the scrap area SA. For example, as the rack moves in the +x direction, the pinion 1431 and the arm 1432 may rotate clockwise. In an embodiment, as the arm 1432 rotates clockwise, the fixing part 1430 connected to the arm 1432 may directly contact the upper surface of the scrap area SA. For example, the fixing part 1430 may press the upper surface of the scrap area SA in the −z direction.

Referring to FIG. 12, a blade may saw the package substrate 200. The blade may cut the package substrate 200 along sawing lines positioned between adjacent package areas PA, between adjacent scrap areas SA, and between adjacent package areas PA and scrap areas SA. During the sawing process, the package area PA may be vacuum-absorbed to be fixed on the package pad part 122, and the scrap area SA may be fixed on the scrap pad part 121 by the force pressed by the fixing part 1430.

By the sawing process, the scrap area SA may become the scrap 25, and the package area PA may become the semiconductor package 20.

Referring to FIG. 13, the vacuum pressure applied to the vacuum pipe 130 may be released. For example, in an embodiment, as a picker picks up at least one semiconductor package 20 generated by sawing, the vacuum pressure applied to the vacuum pipe 130 may be released. As the vacuum pressure is released to the vacuum pipe 130, the package area PA (e.g., the semiconductor package 20 by the sawing process) may no longer be vacuum-adsorbed. As the vacuum pressure is released to the vacuum pipe 130, the fixing device 140 may move away from the upper surface of the scrap area SA (e.g., the scrap 25 by the sawing process).

When the vacuum pressure is released to the vacuum pipe 130, the compression of the compression member 141 may be released. For example, the length of the compression member 141 may increase in the +x direction to be restored to its original length. As the compression is released, the compression member 141 may push the moving member 142 in the −x direction.

The moving member 142 may move in the −x direction within the vacuum pipe 130 by the pushing force of the compression member 141. For example, the moving member 142 that is a rack may move in the −x direction.

The fixing member 143 including the fixing part 1430, connected to the moving member 142 may move away from the upper surface of the scrap area SA. For example, as the rack moves in the −x direction, the pinion 1431 and the arm 1432 may rotate counterclockwise. As the arm 1432 rotates counterclockwise, the fixing part 1430 connected to the arm 1432 may move away from the upper surface of the scrap area SA.

The moving direction of the moving member 142 and the rotating direction of the pinion 1431 and the arm 1432 described above with reference to FIG. 10 to FIG. 13 are directions applied to the fixing device 140 at a position corresponding to the area A of FIG. 1 among the plurality of fixing devices 140 included in the chuck table 100, and the moving direction of the fixing device 140 at another position may be different from the direction described above.

While embodiments of the present disclosure have been described, it is to be understood that embodiments of the present disclosure are not limited to the described embodiments, but, on the contrary, is intended to cover various modifications and equivalent arrangements included within the spirit and scope of the present disclosure.

What is claimed is:

1. A chuck table comprising:
a support part receiving a package substrate, the package substrate including a package area having a plurality of semiconductor packages arranged thereon and a scrap area surrounding the package area, the scrap area does not include the plurality of semiconductor packages;
a package pad part disposed between the support part and the package substrate, the package pad part directly contacting the package area;
a scrap pad part disposed between the support part and the package substrate, the scrap pad part directly contacting the scrap area;
a vacuum pipe extending through the package pad part and extending into the support part, the vacuum pipe has vacuum pressure applied thereto and has the vacuum pressure released therefrom; and
a fixing device that is connected to the vacuum pipe, the fixing device moves closer to an upper surface of the scrap area as the vacuum pressure is applied to the vacuum pipe, and moves away from the upper surface of the scrap area as the vacuum pressure is released from the vacuum pipe.

2. The chuck table of claim 1, wherein:
the package pad part includes a plurality of package pads;
the scrap pad part includes a plurality of scrap pads; and
each of the plurality of package pads and the plurality of scrap pads are spaced apart from each other.

3. The chuck table of claim 2, wherein the vacuum pipe includes:
a plurality of through-pipes penetrating the plurality of package pads;
a connection pipe connecting the plurality of through-pipes to each other; and
an extension pipe extending from the connection pipe to an edge portion of the support part.

4. The chuck table of claim 3, wherein:
the fixing device is directly connected to the extension pipe.

5. The chuck table of claim 1, wherein the fixing device includes:
a compression member having a length that is compressed by the vacuum pressure applied to the vacuum pipe and restored when the vacuum pressure is released,
a moving member connected to the compression member, the moving member enters the vacuum pipe when the length of the compression member is compressed by the vacuum pressure and exits the vacuum pipe when the length of the compression member is restored by the release of the vacuum pressure; and
a fixing member connected to the moving member and having a distance from the scrap area adjusted according to a moving direction of the moving member.

6. The chuck table of claim 5, wherein:
the fixing member includes a fixing part contacting one surface of the scrap area; and
the fixing part is tiltable.

7. The chuck table of claim 6, wherein:
the contact portion of the fixing part includes a material having elasticity; and
the contact portion has a round shape.

8. The chuck table of claim 5, wherein:
the moving member includes a rack; and
the fixing member includes:
a pinion that rotates in engagement with the rack; and
an arm that rotates by the rotation of the pinion.

9. The chuck table of claim 5, wherein:
the fixing member includes:
a first link rotatably connected to the support part; and
a second link rotatably connected to the first link and the moving member,
wherein the first and second links rotate by movement of the moving member.

10. The chuck table of claim 5, wherein:
the fixing member linearly moves in a direction parallel to the moving direction of the moving member based on movement of the moving member.

11. A chuck table comprising:
a support part receiving a package substrate, the package substrate including a package area having a plurality of semiconductor packages arranged thereon and a scrap area surrounding the package area;
a package pad part disposed between the support part and the package substrate, the package pad part directly contacting the package area;
a scrap pad part disposed between the support part and the package substrate, the scrap pad part directly contacting the scrap area;
a vacuum pipe extending through the package pad part and extending into the support part, the vacuum pipe has vacuum pressure applied thereto and has the vacuum pressure released therefrom; and
a fixing device connected to the vacuum pipe and driven by the vacuum pressure applied to the vacuum pipe,
wherein the fixing device includes:
a compression member compressed by the vacuum pressure applied to the vacuum pipe and having a restoring force,
a moving member connected to the compression member, the moving member is movable in the vacuum pipe by the application or release of the vacuum pressure, and
a fixing member connected to the moving member and having a distance from the scrap area adjusted according to a moving direction of the moving member.

12. The chuck table of claim 11, wherein:
the fixing member includes a fixing part contacting one surface of the scrap area; and
the fixing part is tiltable.

13. The chuck table of claim 11, wherein:
the package pad part is disposed in a central area of the support part in a plan view;
the scrap pad part is disposed in an edge area of the support part, the scrap pad part surrounding the package pad part in the plan view; and
the fixing device is disposed adjacent to the scrap pad part.

14. The chuck table of claim 11, wherein:
a plurality of fixing devices are disposed to be spaced apart from each other along the scrap pad part.

15. A semiconductor package manufacturing method, comprising:
preparing a package substrate including a package area having a plurality of semiconductor packages arranged thereon and a scrap area surrounding the package area;
positioning the package substrate on a chuck table including a vacuum pipe that adsorbs the package area and a fixing device that is connected to the vacuum pipe and positions and fixes the scrap area;
applying vacuum pressure to the vacuum pipe;
sawing the package substrate to singulate the plurality of semiconductor packages; and
releasing the vacuum pressure to the vacuum pipe,
wherein in the applying of the vacuum pressure to the vacuum pipe, the fixing device approaches an upper surface of the scrap area, and
in the releasing of the vacuum pressure to the vacuum pipe, the fixing device moves away from the upper surface of the scrap region.

16. The semiconductor package manufacturing method of claim 15, wherein the vacuum pressure is released by picking up at least one semiconductor package singulated by the sawing.

17. The semiconductor package manufacturing method of claim 15, wherein the applying of the vacuum pressure to the vacuum pipe includes:
compressing a compression member of the fixing device;
moving a moving member of the fixing device connected to the compression in a direction pulled by the compression member within the vacuum pipe; and
approaching an upper surface of the scrap area by a fixing member connected to the moving member.

18. The semiconductor package manufacturing method of claim 17, wherein the releasing of the vacuum pressure to the vacuum pipe includes:
releasing the compression of the compression member;
the moving member moves in a direction pushed by the compression member in the vacuum pipe; and
the fixing member moves away from an upper surface of the scrap area.

19. The semiconductor package manufacturing method of claim 18, wherein the fixing member rotates in a direction corresponding to a moving direction of the moving member.

20. The semiconductor package manufacturing method of claim 18, wherein the fixing member linearly moves in a direction parallel to a moving direction of the moving member.
